(19) United States
(12) Patent Application Publication
(10) Pub. No.: US 2007/0262782 A1
(43) Pub. Date: Nov. 15, 2007

(54) METHOD FOR COMPENSATION FOR A POSITION CHANGE OF A PROBE CARD

(75) Inventor: Udo Hartmann, Neuried (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/746,851

(22) Filed: May 10, 2007

(30) Foreign Application Priority Data
May 13, 2006 (DE) 10 2006 022 475.2

(51) Int. Cl. G01R 31/02

(52) U.S. Cl. 324/754

(57) ABSTRACT

A method for compensation for a position change of a probe card is disclosed. In one embodiment, during the course of a functional test of an integrated circuit which is arranged on a semiconductor wafer includes determination of a temperature of the probe card and matching of the position of the semiconductor wafer to the temperature-dependent position change of the probe card. Matching of the position of the semiconductor wafer is carried out on the basis of the determined temperature and of a family of characteristics which reflects the temperature-dependent position change of the probe card.

### CROSS-REFERENCE TO RELATED APPLICATIONS

This Utility Patent Application claims priority to German Patent Application No. DE 10 2006 022 475.2 filed on May 13, 2006, which is incorporated herein by reference.

### BACKGROUND

Probe cards are used for high-parallelity functional testing of integrated circuits on a semiconductor wafer, referred to in the following text as a wafer. A probe card, which is connected to a tester for the functional test, has a mount device on which an arrangement of sprung test probes, contact probes, is arranged in a very small space. An electrical connection is produced between the individual contact probes and the tester via the mount device.

During functional testing of integrated circuits, the semiconductor wafer is arranged on a table which may be moved in all directions, a chuck, of a test device which is referred to as a wafer tester. The wafer tester allows precise adjustment of the position of the chuck, in order to adjust contact points, which are provided on the wafer, accurately under corresponding contact probes of the probe card, which is installed in a fixed form in the wafer tester. For this purpose, the wafer tester has a device for electronic image detection and evaluation. The contact points are generally metallic test contact pads, which are arranged on the wafer and are electrically connected to the integrated circuits. The contact points may also optionally be in the form of contact bumps.

As soon as the chuck has been positioned with the aid of the wafer tester such that the contact points or pads are exactly aligned with corresponding contact probes, the chuck is moved against the contact probes of the probe card by the wafer tester such that the contact probes press against the pads on the semiconductor wafer with a predetermined force, or a predetermined contact pressure, and at the same time “bore” into the pads, in order to allow a reliable contact to be made with the pads and thus with the integrated circuits connected to the pads on the wafer. High-parallelity probe cards that are used at the moment may have a total number of contact probes in the region of ten thousand or more, so that more than one hundred integrated circuits may be tested in parallel using probe cards such as these.

The contact probes on a probe card are provided with a certain amount of spring elasticity, with the spring movement being restricted to a maximum of for example 100 μm. During the movement of the chuck against the probe card, the chuck is moved through, for example, 50 μm more in the direction of the probe card after initial contact between the contact probes on the probe card and the pads on the wafer, in order to produce the contact pressure as described above for reliable contact. In a situation such as this, there is a predetermined “contact-pressure range” for a functional test, which corresponds to an exemplary movement range between 50 and 100 μm after initial contact between the contact probes and the pads. If the contact probes are pushed on more strongly than the maximum permissible spring movement, this leads to permanent plastic deformation, and thus to defective contact probes.

During a functional test, the tester applies test signals via the probe card to the integrated circuits with which contact is being made, and receives response signals, in a corresponding manner, from the integrated circuits. The temperature stability of the integrated circuits may also be tested during this process. For this purpose, the semiconductor wafer is for example raised to a test temperature of up to 125° C. with the aid of heating in the chuck. During a functional test such as this with a heated wafer, the probe card is also necessarily heated. This takes place via the contact probes which are seated on the pads on the wafer, and which may be manufactured from a high-strength metal, thus having a good thermal conductivity. However, the probe card is heated mainly by the thermal radiation emitted from the wafer.

The mount device for a probe card may be in the form of a printed circuit board (PCB) in which conductor tracks are provided for connection of the individual contact probes. The printed circuit board may additionally be provided with metal reinforcement in order to prevent its weight causing bending. The thermal heating of the probe card during a test process with a heated wafer may lead to thermal expansion of the mount device, which results in the position of the probe card, which is installed such that it is fixed in the wafer tester, being changed with respect to the wafer to be tested.

In addition to lateral position changes in the XY direction, which may result in “scratching” and thus in possible destruction of pads by the contact probes, movements may occur in particular in the Z direction, and thus a change in the distance between the probe card and the semiconductor wafer. This may result in the contact probes being compressed during the course of a functional test, for example, so severely that the maximum tolerable spring movement or contact pressure is exceeded, and the contact probes are permanently deformed.

In addition, it is possible for a temperature change of the probe card during a functional test to increase the distance between the probe card and the wafer such that this results in inadequate contact pressure between the contact probes on the probe card and the pads on the wafer, and/or in a contact which has already been made with the pads being disconnected again. This may result in integrated circuits to be tested incorrectly being classified as defective, resulting, in consequence, in yield losses.

In order to avoid such position changes, caused by temperature changes, of a probe card during the course of functional testing of integrated circuits, the wafer may be moved as close as possible to the probe card, with the chuck, before the heating or cooling process. A predetermined time period may then be allowed to elapse for the probe card to heat up or cool down, after which it is assumed that the probe card is in thermal equilibrium and that, in consequence, the probe card will remain in the same position from then on. Subsequently, the wafer may be aligned with respect to the probe card with the aid of the chuck for the functional test, and may be moved towards the probe card in order to produce a contact between the contact probes on the probe card and the pads on the wafer.

However, a procedure such as this is associated with a relatively long time penalty. In addition, it is not possible to functionally test any integrated circuits during the time in which a probe card is being heated up or cooled down. Furthermore, different types of probe cards, which differ from one another for example in the size or the materials of individual components of the probe cards and/or of the mount devices, require different warming-up and cooling-down times. In practice the aim is therefore to define a standard maximum time period for different types of probe cards to warm up and to cool down. If this time period is not observed or a probe card is not yet in thermal equilibrium despite having waited for the predetermined time period, there is the risk of the probe card being subjected to a temperature-dependent position change during the course of a functional test, with the consequences, as described above, of damaged pads on the semiconductor wafer and contact probes on the probe card, as well as incorrect assessment of integrated circuits to be tested.

### SUMMARY

One embodiment is a method for compensation for positioning change of a probe card. In one embodiment, during the course of a functional test of an integrated circuit which is arranged on a semiconductor wafer includes determination of a temperature of the probe card and matching of the position of the semiconductor wafer to the temperature-dependent position change of the probe card. Matching of the position of the semiconductor wafer is carried out on the basis of the determined temperature and of a family of characteristics which reflects the temperature-dependent position change of the probe card.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic illustration of a test apparatus.

FIGS. 2 and 3 illustrate measured temperature-dependent position changes of probe cards as a function of time.

FIG. 4 illustrates a flowchart of a method for compensation for a temperature-dependent position change of a probe card.

FIGS. 5 to 8 illustrate flowcharts of methods, in which a temperature-dependent position change of a probe card in the course of functional testing is compensated for.

FIG. 9 illustrates a schematic illustration of another test apparatus.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Embodiments relate to a method for compensation for a position change, caused by a temperature change, of a probe card during the course of a functional test of an integrated circuit which is arranged on a semiconductor wafer. The probe card includes a mount device with an arrangement of test probes for making contact with contact points which are arranged on the semiconductor wafer and which are connected to the integrated circuit. Embodiments also relate to a test apparatus, in which a temperature-dependent position change of a probe card may be compensated for.

A method for compensation for a position change, caused by a temperature change, of a probe card during the course of a functional test of (at least) one integrated circuit which is arranged on a semiconductor wafer, includes determination of a temperature of the probe card and matching of the position of the semiconductor wafer to the temperature-dependent position change of the probe card. Matching of the position of the semiconductor wafer is carried out on the basis of the determined temperature and of a family of characteristics which reflects the temperature-dependent position change of the probe card. In this way the position change, caused by the temperature change, of the probe card may be compensated for.

This method is based on correction of the position of the semiconductor wafer on the basis of the instantaneous temperature of the probe card and of the family of characteristics which reflects the temperature-dependent position change of the probe card, instead of having to wait for a predetermined time period, after which it is assumed that the probe card is in thermal equilibrium. This makes it possible to align the semiconductor wafer for contact with the probe card even before a heating or cooling process, thus making it possible to functionally test the integrated circuit that is arranged on the semiconductor wafer with less time being required. Furthermore, the method may avoid damage to contact points on the semiconductor wafer and to test probes of the probe card placed on contact points, resulting from a predetermined maximum contact pressure being exceeded. In addition, the risk of the integrated circuit being incorrectly assessed as defective during a functional test, as a result of an inadequate contact between the test probes of the probe card and the contact points on the semiconductor wafer, may be avoided.

The matching of the position of the semiconductor wafer may be carried out during the position change, caused by the temperature change, of the probe card. This allows the test time for a functional test to be considerably reduced.

Furthermore, the matching of the position of the semiconductor wafer to the position change, caused by the temperature change, of the probe card may be carried out at predetermined time intervals, which are interrupted by time intervals in which the position of the semiconductor wafer is not changed, in order to carry out the matching of the position of the semiconductor wafer to the position change, caused by the temperature change, of the probe card in processes.

In this case, a time interval in which the position of the semiconductor wafer is not changed, may be shorter than a time interval in which a characteristic parameter which relates to a contact between a test probe of the probe card and a contact point on the semiconductor wafer leaves a predetermined range as a result of the position change, caused by the temperature change, of the probe card. This allows reliable contact to be made between test probes of the probe card and corresponding contact points on the semiconductor wafer during a heating or cooling process, without the risk of damage to test probes or to the probe card.

A contact pressure between a test probe of the probe card and a contact point on the semiconductor wafer may be used as the characteristic parameter relating to a contact. The contact pressure may in this case be quoted in the form of an additional movement distance of the semiconductor wafer in the direction of the probe card from a first contact between test probes on the probe card and contact points on the semiconductor wafer.

Test signals for functional testing may be applied to the integrated circuit in a time interval in which the position of the semiconductor wafer is not changed. This makes it possible to avoid vibration, which affects the integrated circuit and may occur when the position of the semiconductor wafer is changed, having a negative effect on the functional test, so that the functional test of the integrated circuit may be carried out with high reliability and accuracy while the temperature of the probe card is changing.

Alternatively, the matching of the position of the semiconductor wafer may be carried out after the position change, caused by the temperature change, of the probe card.

The family of characteristics may additionally reflect the temperature-dependent position change of the probe card as a function of time. This allows the position of the semiconductor wafer to be matched with high accuracy to the temperature-dependent position change of the probe card, which for example applies to the case of the aforesaid step-by-step matching process of the position of the semiconductor wafer to the position change of the probe card.

A test apparatus in which a position change, caused by a temperature change, of a probe card may be compensated for includes a probe card which has a mount device with an arrangement of test probes for making contact with contact points arranged on a semiconductor wafer, with the contact points being connected to (at least) one integrated circuit which is arranged on the semiconductor wafer, a holding device for holding the semiconductor wafer, for changing the position of the semiconductor wafer with respect to the probe card and for changing the temperature of the semiconductor wafer, and a control device for controlling the variation, which is carried out with the aid of the holding device, of the position and of the temperature of the semiconductor wafer, and for application of test signals to the integrated circuit for functional testing. The test apparatus further includes a temperature detection device for determination of a temperature of the probe card, as well as an evaluation device for determination of a position, which is matched to a position change, caused by a temperature change, of the probe card, of the semiconductor wafer on the basis of the determined temperature and of a family of characteristics which reflects the temperature-dependent position change of the probe card, in order to compensate for the position change, caused by the temperature change, of the probe card.

In a corresponding manner, the test apparatus makes it possible to align the semiconductor wafer with respect to the probe card even before a heating or cooling process for contact, and to match the position of the semiconductor wafer to the temperature-dependent position change of the probe card after or even during the heating or cooling process, so that the functional testing of the integrated circuit may be carried out with little time penalty. Furthermore, the risk of damage to contact points on the semiconductor wafer and to contact probes on the probe card resulting from a maximum contact pressure being exceeded, and the risk of the integrated circuit being assessed incorrectly as being defective as a result of inadequate contact between the test probes on the probe card and the contact points on the semiconductor wafer, during functional testing, may be avoided.

Further embodiments for compensation for a temperature-dependent position change of a probe card are explained in conjunction with the drawings.

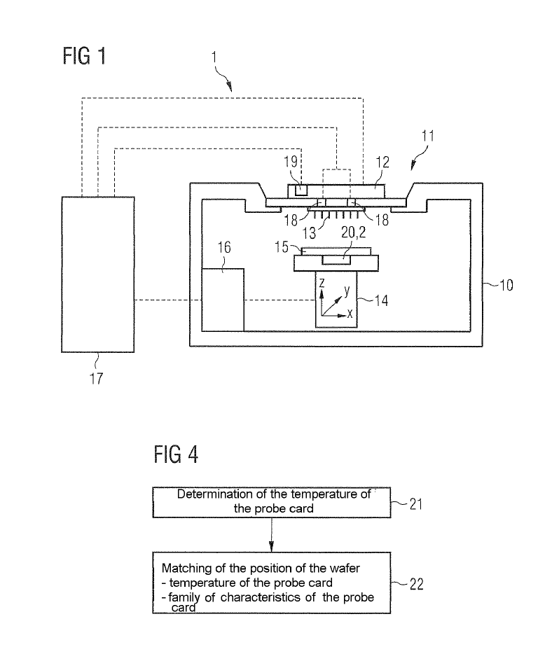

FIG. 1 illustrates a schematic illustration of a test apparatus 1, which is used for testing the functionality of integrated circuits on a semiconductor wafer 15. The test apparatus 1 includes a wafer tester 10 with a holding device 14, which has a chuck which may be moved in the XY and Z directions, for exact adjustment of the wafer 15. For this purpose, the wafer 15 is held firmly on the chuck of the holding device 14, for example, using vacuum pressure. In this case, the X and Y directions relate, for example, to a plane which is predetermined by a surface of the wafer 15 while, in contrast, the Z direction runs at right angles to this plane. A tester controller 16 is provided in order to control the movement of the chuck. The tester controller 16 is in this case able to completely automatically finely adjust the chuck, for example with the aid of electronic image recognition.

In order to allow the integrated circuits arranged on the wafer 15 to additionally be subjected to a functional test at raised temperatures, the chuck of the holding device 14 has a heating element 20 by which the wafer 15 may be heated to an intended test temperature. By way of example, a functional test is carried out at a temperature of up to 125° C. on of the wafer 15, in order to make it possible to ensure the functionality of the integrated circuits on the wafer 15, even at operating temperatures such as these. The heating element 20 is switched on by the tester controller 16, for this purpose.

A probe card 11 which is installed fixed to the wafer tester 10 is provided for carrying out a functional test. The probe card 11 includes a mount device 12 with an arrangement of contact probes 13. The mount device 12 may for example be a printed circuit board in which conductor tracks are provided for connection of the individual contact probes 13. Furthermore, the mount device 12 may comprise, for example, metal reinforcement, in order to prevent the weight of the probe card 11 causing it to bend.

The contact probes 13 on the probe card 11 are designed to make contact with contact points which are arranged on the wafer 15 and produce the connection to the integrated circuits on the wafer 15, and which may be arranged in intermediate areas between the integrated circuits on the wafer 15. By way of example, the contact points are in the form of metallic contact pads. In order to make contact with the contact points or pads, the wafer 15 is first of all moved with the aid of the chuck of the holding device 14 and is aligned with respect to the probe card 11 such that the pads are precisely opposite corresponding contact probes 13. The chuck is then moved against the probe card 11 in the Z direction in such a way that contact probes 13 press against corresponding pads on the wafer 15.

The contact probes 13 on the probe card 11 are designed to be elastic, in order to produce a predetermined contact pressure between the contact probes 13 and the pads, in order to make reliable contact. In this case, a contact pressure is produced in the form of an additional movement distance of the wafer 15 in the direction of the probe card 13 of, for example, 50 μm after initial contact between the contact probes 13 on the probe card 11 and corresponding pads on the semiconductor wafer 15. The maximum contact pressure is limited by the maximum spring movement of the contact probes 13 which, for example, is 100 μm. If the contact probes 13 are compressed beyond the maximum permissible spring movement, there is a risk of permanent plastic deformation of the contact probes 13 occurring, thus damaging the probe card 11.

The test apparatus 1 also includes a tester 17, which is connected to the probe card 11, in order to generate test signals for the functional test, with these test signals being applied to the pads, and thus to the integrated circuits on the wafer 15, via the probe card 11. Response signals may be received and evaluated by the tester 17 in a corresponding manner. The tester 17 is connected to the tester controller 16 via an interface such as a GPIB (General Purpose Interface Bus), in order to predetermine test positions of the wafer 15 for the functional test for the tester controller 16, and to activate the heating element 20 via the tester controller 16. Furthermore, before a functional test, test signals may be repeatedly applied via the tester 17 in the form of a contact test loop to the probe card 11 for adjustment of the wafer 15, in order to complement the electronic image recognition.

Heating of the wafer 15 in the course of a functional test results in thermal heating of the probe card 11. The probe card 11 is primarily heated by the thermal radiation emitted from the wafer 15. In addition, the probe card 11 is also heated by thermal conduction via the contact probes 13 that touch the wafer 15. The heating of the probe card 11 leads to thermal expansion of the mount device 12, thus changing the position of the probe card 11, which is installed fixed in the wafer tester 10, and thus the position of the contact probes 13, with respect to the wafer 15 to be tested. In addition to a change in the lateral position of the probe card 11 in the X and Y directions, the position of the probe card 11 in this case may change in particular in the Z direction, thus resulting in a change in the distance between the probe card 11 and the wafer 15.

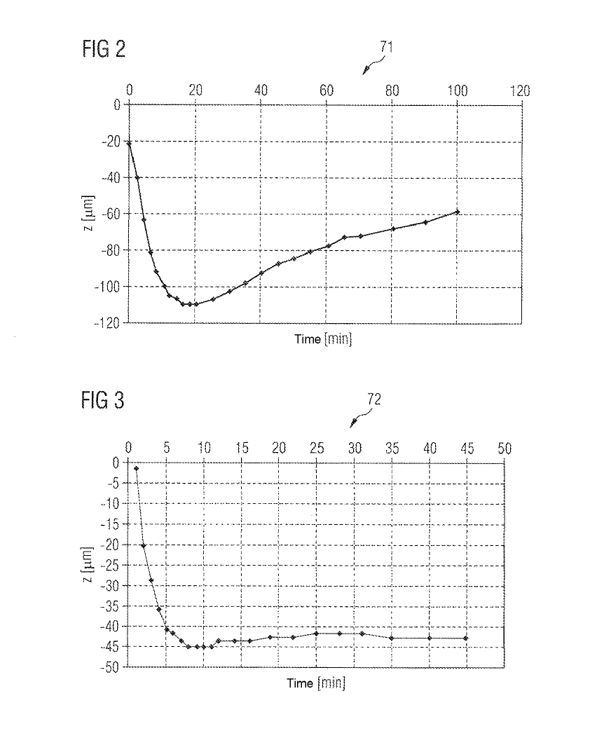

For illustrative purposes, FIGS. 2 and 3 illustrate measured temperature-dependent position changes 71, 72 of two different probe cards in the Z direction as a function of time. The thermal heating of the probe cards, which were both heated from room temperature to a temperature of 80° C., was caused by the amount of heat emitted during heating of wafers.

In the case of the position change 71 illustrated in FIG. 2, the probe card first of all moved “downwards” to a minimum Z value of approximately −110 μm at a time of about 18 minutes. After this, the probe card carried out a temperature-dependent movement in the opposite direction as far as a Z value of approximately −60 μm, at a time of approximately 100 minutes. A position change 71 such as this with different movement directions results from the different thermal expansion behavior of the mount device, which is composed of various components and materials, of the probe card being examined.

The position change 72 illustrated in FIG. 3 had a minimum Z value of −45 μm after a heating time of about 8 minutes. From then on, only minor changes occurred to the position of the probe card being examined.

Such position changes, caused by temperature-dependent expansion or else contraction of a mount device 12, of a probe card 11 may also occur in a corresponding manner during functional tests of integrated circuits in which a wafer 15 is cooled down to a predetermined low test temperature in order to test the temperature stability of the integrated circuits. For example, in the case of the test apparatus 1 illustrated in FIG. 1, in addition to or instead of the heating element 20, the wafer tester 10 or the chuck of the holding device 14 may be provided with a device 2, which may be activated by the tester 17 or the tester controller 16, for cooling of the wafer 15. The cooling down of the probe card 11 which is caused by this may also result in lateral position changes, that is to say in the X and Y directions, in addition to position changes occurring in the Z direction.

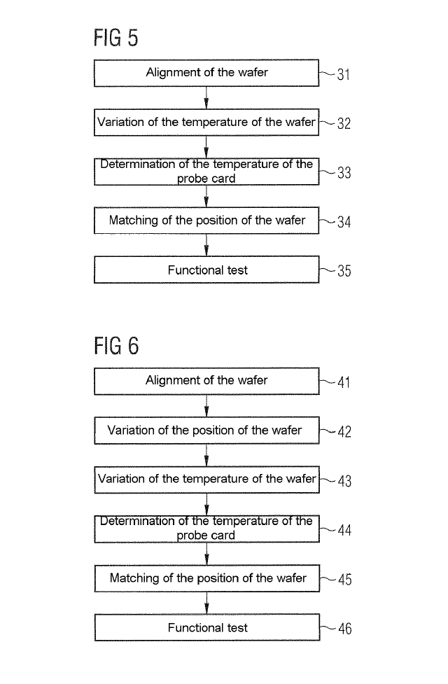

In order to compensate for such temperature-dependent position changes of the probe card 11 in the case of the test apparatus 1 illustrated in FIG. 1 in the course of functional testing of integrated circuits arranged on the wafer 15, the method as illustrated in FIG. 4 may be carried out. The temperature of the probe card 11 is determined for this purpose, in a method process 21. For this purpose, the probe card 11 has at least one temperature sensor 18, which is arranged on the probe card 11. By way of example, the temperature sensors 18 may be in the form of thermocouples which are arranged at suitable points on the probe card 11 or on the mount device 12, such that the temperature of the probe card 11 may be recorded as close to real time as possible.

In a further method process 22, the position of the wafer 15 is matched with the aid of the chuck of the holding device 14 to the position change, caused by the temperature change, of the probe card 11 on the basis of the determined temperature of the probe card 11 and of a family of characteristics which reflects the temperature-dependent position change of the probe card 11. The family of characteristics of the probe card 111 may be based on calibration measurements for the temperature-dependent position change of the probe card 11, carried out subject to identical or comparable constraints in terms of heating of the probe card 11 (initial temperature, final temperature and test temperature, thermal power emitted, etc). In the case of the test apparatus 1 illustrated in FIG. 1, the family of characteristics for the probe card 11 may be stored in a memory 19 on the probe card 11, for example algorithmically or in the form of a table of discrete values. In this case, the memory 19 may be a non-volatile memory, for example a flash memory.

The determination of the position, matched to the temperature-dependent position change of the probe card 11, of the wafer 15 is carried out in the case of the test apparatus 1 illustrated in FIG. 1 by using the tester 17, which acts as an evaluation device and is connected via appropriate connection lines to the memory 19 in order to read the family of characteristics for the probe card 11, and is connected to the temperature sensors 18 in order to detect the instantaneous temperature of the probe card 11. The determined matched position of the probe card 11 is then transmitted from the tester 17 to the tester controller 16, in order to appropriately correct the position of the wafer 15 with the aid of the chuck of the holding device 14.

In addition to the change in the position of the probe card 11 as a function of the temperature, the family of characteristics may also reflect the change in the position of the probe card 11 as a function of time. Time recording, carried out for example with the aid of the tester 17 or the tester controller 16, in particular makes it possible in this way to predict the change in the position of the probe card 11 which will occur as further time elapses, on the basis of an instantaneously measured temperature value of the probe card 11. This allows the position of the wafer 15 to be matched to the temperature-dependent position change of the probe card 11 with high accuracy.

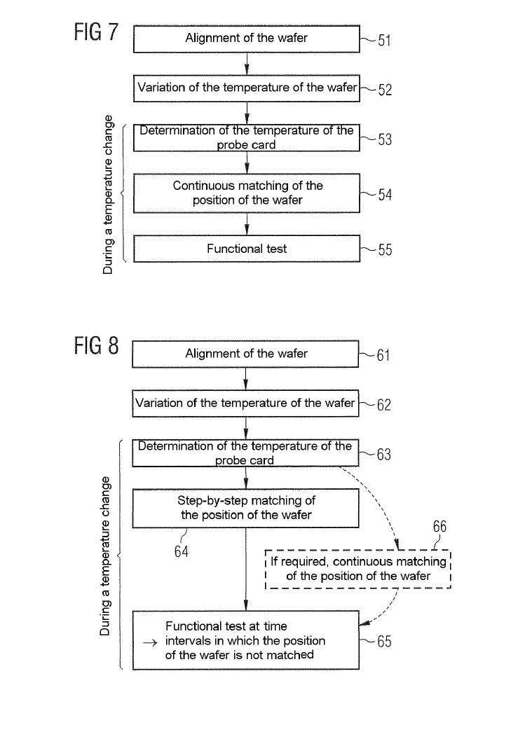

Functional testing of integrated circuits which are arranged on the wafer 15 may be carried out in various ways on the basis of the method processes 21, 22 in the method as illustrated in FIG. 4. For this purpose, the following FIGS. 5 to 8 illustrate flowcharts of methods, in which a temperature-dependent position change of the probe card 11 during the course of functional testing of integrated circuits is compensated for. In the case of the methods illustrated in FIGS. 5 and 6, the position of the wafer 15 is in each case matched after the temperature-dependent position change of the probe card 11, and in the case of the methods illustrated in FIGS. 7 and 8, it is in each case matched during the temperature-dependent position change of the probe card 11.

In the method illustrated in FIG. 5, the wafer 15 is first of all aligned with respect to the probe card 11 and the contact probes 13, and is moved towards the probe card 11 such that the contact probes 13 make contact with corresponding pads on the wafer 15 with a predetermined contact pressure (method process 31). The temperature of the wafer 15 is then changed for functional testing (method process 32), as a result of which the temperature of the probe card 11, and thus the position of the probe card 11, also change. By way of example, the wafer 15 may be heated to a predetermined test temperature with the aid of the heating element 20. Alternatively, it is possible for the wafer 15 to be cooled down to a predetermined low test temperature with the aid of the cooling device 2.

In a further method process 33, the temperature of the probe card 11 is determined with the aid of the temperature sensors 18, which are arranged on the probe card 11. This may be done continuously during the heating or cooling process of the probe card 11, in order to determine the earliest possible time at which the probe card 11 has reached the predetermined test temperature of the wafer 15, and is in thermal equilibrium. It is also possible if required to determine the temperature of the probe card 11 in processes at predetermined time intervals during the heating or cooling process, or else to record the temperature of the probe card 11 after a predetermined waiting time.

As soon as the probe card 11 has reached the predetermined test temperature, the position of the wafer 15 is matched to the temperature-dependent position change of the probe card 11 on the basis of the determined temperature and of the family of characteristics for the probe card 11 (method process 34). Test signals for functional testing are then applied via the contact probes 13 on the probe card 11 from the tester 17 to the integrated circuits on the wafer 15 (method process 35). If, in the case of the method illustrated in FIG. 5, the wafer 15 is moved to a position in which it makes contact with the probe card 11, even before the temperature change and the position change that this results in of the probe card 11, one precondition for this movement is that the probe card 11 does not exceed the maximum spring movement of the contact probes 13 during a movement in the Z direction in the direction of the wafer 15, in order to preclude damage to the contact probes 13. Furthermore, another precondition is that any lateral movement in the X and Y directions is negligibly small, in order to avoid scratching of pads.

FIG. 6 illustrates an alternative embodiment of a method for matching the position of the wafer 15 on the basis of the temperature-dependent position change of the probe card 11, in which the probe card 11 may also carry out a temperature-dependent movement in the Z direction, in the direction of the wafer 15, beyond the maximum spring movement of the contact probes 13, as well as a significant lateral movement in the X and Y directions. First of all, the wafer 15 is once again aligned with respect to the probe card 11 and is moved to a position in which it makes contact with the probe card 11 with a predetermined contact pressure (method process 41). The position of the wafer 15 is then changed, in contrast to the method illustrated in FIG. 5, in particular by a downward movement (in the Z direction) of the chuck of the holding device 14, such that there is no longer any contact between the probe card 11 and the wafer 15 (method process 42). This change in the position of the wafer 15 is, for example, stored in the tester 17 or in the tester controller 16.

The temperature of the wafer 15 is subsequently once again changed by heating or cooling (method process 43), and the temperature of the probe card 11 is determined, for example continuously, while the temperature of the probe card 11 is being changed in this way (method process 44).

As soon as the probe card 11 has reached the predetermined test temperature, the position of the wafer 15 is once again matched to the position of the probe card 11 on the basis of the determined temperature and of the family of characteristics for the probe card 11 (method process 45), in this case taking account not only of the temperature-dependent position change of the probe card 11 but also of the stored position change, carried out in order to disconnect the contact between the wafer 15 and the probe card 11, in method process 42. This is once again followed by functional testing of the integrated circuits arranged on the wafer 15 (method process 46).

FIG. 7 illustrates a further method, in which the wafer 15 is first of all aligned with respect to the probe card 11 and is moved to a position in which it makes contact with the probe card 11 with a predetermined contact pressure (method process 51), and the wafer 15 is heated or cooled to the predetermined test temperature (method process 52). While the temperature is changing as a result of this, not only is the temperature of the probe card 11 determined continuously (method process 53), but the position of the wafer 15 is also matched to the temperature-dependent position change of the probe card 11 continuously on the basis of the (respectively) determined temperature and of the family of characteristics for the probe card 11 (method process 54). At the same time, test signals for functional testing are applied to the integrated circuits even while the temperature of the probe card 11 is changing (method process 55). In this case, the wafer 15 may have already reached the predetermined test temperature, and this may be ensured by using temperature sensors which, for example, make contact with the wafer 15, in order to record the temperature of the wafer 15.

In the method illustrated in FIG. 8, the wafer 15 is first of all aligned in a corresponding manner with respect to the probe card 11, and is moved to a position in which it makes contact with the probe card 11 (method process 61), and the wafer 15 is heated or cooled to the predetermined test temperature (method process 62). The temperature of the probe card 11 is once again determined while the temperature is changing as a result of this (method process 63). In contrast to the method illustrated in FIG. 7, in the method illustrated in FIG. 8, the position of the wafer 15 is, however, matched in processes to the change in position of the probe card 11 resulting from the temperature change (method process 64). In this case, the position of the wafer 15 is matched at predetermined time intervals, which are interrupted by fixed time intervals in which the position of the wafer 15 is not changed.

In particular in this method, the advantage of a family of characteristics which reflects the change in position of the probe card 11 as a function of time may be apparent, since the time intervals may in this way be matched to one another with high accuracy, in particular such that a time interval in which the position of the wafer 15 is not changed is shorter than a time interval in which a characteristic parameter which relates to a contact between a contact probe 13 on the probe card 11 and a pad on the wafer 15 leaves a predetermined range as a result of the position change, caused by the temperature change, of the probe card 11. The characteristic parameter may be the contact pressure between a contact probe 13 on the probe card 11 and a pad on the wafer 15. This allows reliable contact to be made without any risk of damage to the contact probes 13 or to the probe card 11.

In the time intervals in which the position of the wafer 15 is not changed, test signals for functional testing are applied to the integrated circuits on the wafer 15 for the method as illustrated in FIG. 8 (method process 65). This means that the functional testing of the integrated circuits may be carried out with high reliability and accuracy, since vibration which adversely affects the functional test and may occur when the position of the wafer 15 is being changed is avoided.

It is likewise possible for a relatively large temperature-dependent position change of the probe card 11 to occur in a time period while the temperature of the probe card 11 is changing, so that it is not possible to define any time intervals for application of test signals to the integrated circuits in which the characteristic parameter remains within its predetermined range. In time periods such as these, in the case of the method illustrated in FIG. 8, the position of the wafer 15 is matched continuously to the temperature-dependent change in position of the probe card 11 (method process 66) without having to apply test signals to the integrated circuits, instead of carrying out step-by-step matching (method process 64). In this case, as well, a family of characteristics which reflects the change in position of the probe card 11 as a function of time may be advantageous since this allows the step-by-step matching of the position of the wafer 15, as carried out in method process 64, and the continuous matching, as carried out in method process 66, to be matched to one another with high accuracy.

Since, in the case of the methods as illustrated in FIGS. 5 to 8, the wafer 15 is already aligned with respect to the probe card 11 before a heating or cooling process for making contact, functional testing of the integrated circuits arranged on the wafer 15 may be carried out with little time penalty. Furthermore, damage to contact points or pads on the wafer 15 as well as damage to contact probes 13 resulting from the predetermined maximum contact pressure being exceeded may be avoided. Furthermore, there is no risk of the integrated circuits being incorrectly assessed as being defective because of inadequate contact between the contact probes 13 on the probe card 11 and the pads on the wafer 15. Since, in the case of the methods illustrated in FIGS. 7 and 8 and in contrast to the methods illustrated in FIGS. 5 and 6, the position of the wafer 15 is matched during the temperature-dependent position change of the probe card 11, the test time for functional testing may be further reduced in this way.

The methods illustrated in FIGS. 5 to 8 are not restricted to compensation for a temperature-dependent position change of a probe card 11 which is heated or cooled from room temperature to a predetermined test temperature. For example, the probe card 11 may initially still be approximately at the predetermined test temperature after a wafer 15 being tested has been replaced. The temperature of the probe card 11 will then change in a corresponding manner as a function of the heating or cooling of the next wafer 15 to be tested. In situations such as this as well, the temperature-dependent position change of the probe card 11 may be compensated for with the aid of the methods illustrated in FIGS. 5 to 8, provided that appropriate families of characteristics are available for the probe card 11.

Instead of the methods as described above, in which a temperature-dependent position change of the probe card 11 is compensated for in the course of functional testing, further embodiments are feasible which represent modifications or combinations to or of the methods illustrated in FIGS. 5 to 8. For example, in the case of the method illustrated in FIG. 7, the functional test on the integrated circuits of the wafer 15 (method process 55) may also be carried out only after continuous matching of the position of the wafer 15 (method process 54).

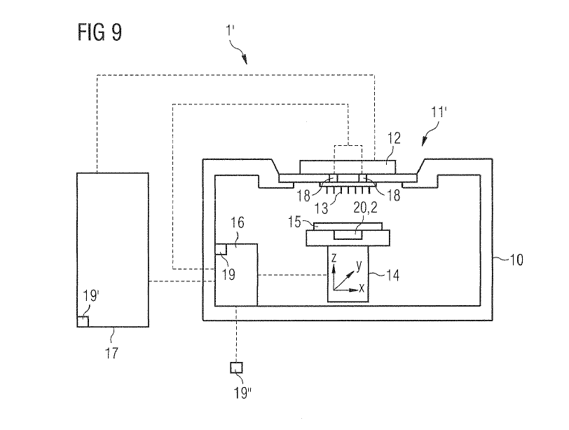

Furthermore, in addition to the test apparatus 1 illustrated in FIG. 1, further embodiments of a test apparatus are feasible, in which a temperature-dependent position change of a probe card may be compensated for on the basis of the method illustrated in FIG. 4 and/or with the aid of the methods illustrated in FIGS. 5 to 8. For this purpose, FIG. 9 illustrates a schematic illustration of a further test apparatus 1′ with a probe card 11′. In contrast to the test apparatus 1 illustrated in FIG. 1, in the case of the test apparatus 1′ illustrated in FIG. 9, the tester controller 16 is used as an evaluation device for determination of the position of the wafer 15 matched to the temperature-dependent position change of the probe card 11′. The temperature sensors 18 for the probe card 11′ are accordingly connected directly to the tester controller 16, via appropriate connecting lines.

Furthermore, in the case of the test apparatus 1′, the memory 19 for the family of characteristics for the probe card 11′ may be integrated directly in the tester controller 16, rather than on the probe card 11′. The tester 17 may also optionally be provided with a memory 19′ for the family of characteristics for the probe card 11′, or an external memory 19″ may be provided.

Instead of the test apparatuses 1, 1′ as illustrated in FIGS. 1 and 9, further embodiments of a test apparatus are feasible, which represent further modifications to or combinations of the test apparatuses 1, 1′. For example, it is possible to provide an evaluation device for determination of a position, which is matched to a temperature-dependent position change of a probe card, of a wafer on the probe card itself. Furthermore, a test apparatus may also have an external evaluation device.

The preceding description describes exemplary embodiments of the invention. The features disclosed therein and the claims and the drawings can, therefore, be useful for realizing the invention in its various embodiments, both individually and in any combination. While the foregoing is directed to embodiments of the invention, other and further embodiments of this invention may be devised without departing from the basic scope of the invention, the scope of the present invention being determined by the claims that follow.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for compensation for a position change of a probe card during the course of a functional test of an integrated circuit which is arranged on a semiconductor wafer, with the probe card comprising a mount device with an arrangement of test probes for making contact with contact points which are arranged on the semiconductor wafer and which are connected to the integrated circuit, the method comprising:
determining a temperature of the probe card; and
matching the position of the semiconductor wafer to the position change of the probe card on the basis of the determined temperature and of a family of characteristics which reflects the temperature-dependent position change of the probe card, in order to compensate for the position change of the probe card.

2. The method according to claim 1, wherein the position change of the probe card is caused by a temperature change.

3. The method according to claim 2, wherein the matching of the position of the semiconductor wafer is carried out during the position change, caused by the temperature change, of the probe card.

4. The method according to claim 3, wherein the matching of the position of the semiconductor wafer to the position change, caused by the temperature change, of the probe card is carried out continuously.

5. The method according to claim 3, wherein the matching of the position of the semiconductor wafer to the position change, caused by the temperature change, of the probe card is carried out at predetermined time intervals, which are interrupted by time intervals in which the position of the semiconductor wafer is not changed, in order to carry out the matching of the position of the semiconductor wafer to the position change, caused by the temperature change, of the probe card in processes.

6. The method according to claim 5, wherein a time interval in which the position of the semiconductor wafer is not changed is shorter than a time interval in which a characteristic parameter which relates to a contact between a test probe of the probe card and a contact point on the semiconductor wafer leaves a predetermined range as a result of the position change, caused by the temperature change, of the probe card.

7. The method according to claim 6, wherein a contact pressure between a test probe of the probe card and a contact point on the semiconductor wafer is used as the characteristic parameter.

8. The method according to claim 6, wherein test signals for functional testing are applied to the integrated circuit in a time interval in which the position of the semiconductor wafer is not changed.

9. The method according to claim 2, wherein the matching of the position of the semiconductor wafer is carried out after the position change, caused by the temperature change, of the probe card.

10. The method according to claim 2, wherein the family of characteristics additionally reflects the position change of the probe card as a function of time.

11. The method according to claim 2, wherein the determination of the temperature of the probe card is carried out by at least one temperature sensor arranged on the probe card.

12. A test apparatus, comprising:
a probe card comprising a mount device with an arrangement of test probes for making contact with contact points arranged on a semiconductor wafer, with the contact points being connected to an integrated circuit which is arranged on the semiconductor wafer;
a holding device for holding the semiconductor wafer, for changing the position of the semiconductor wafer with respect to the probe card and for changing the temperature of the semiconductor wafer;
a control device for controlling the changing, which is carried out with the aid of the holding device, of the position and of the temperature of the semiconductor wafer, and for application of test signals to the integrated circuit for functional testing;
a temperature detection device for determination of a temperature of the probe card; and
an evaluation device for determination of a position, which is matched to a position change of the probe card, of the semiconductor wafer on the basis of the determined temperature and of a family of characteristics which reflects the temperature-dependent position change of the probe card, in order to compensate for the position change of the probe card.

13. The test apparatus according to claim 12, wherein the position of the probe card is caused by a temperature change.

14. The test apparatus according to claim 13, wherein the temperature detection device comprises at least one temperature sensor arranged on the probe card.

15. The test apparatus according to claim 13, further comprising a memory for storage of the family of characteristics of the probe card.

16. A method for compensation for a position change, caused by a temperature change, of a probe card during the course of a functional test of an integrated circuit which is arranged on a semiconductor wafer, with the probe card comprising a mount device with an arrangement of test probes for making contact with contact points which are arranged on the semiconductor wafer and which are connected to the integrated circuit, the method comprising:
determining a temperature of the probe card; and
stepwise matching the position of the semiconductor wafer to the temperature-dependent position change of the probe card at predetermined time intervals, which are interrupted by time intervals in which the position of the semiconductor wafer is not changed, on the basis of the determined temperature and of a family of characteristics which reflects the temperature-dependent position change of the probe card as a function of time, in order to compensate for the position change, caused by the temperature change, of the probe card.

17. The method according to claim 16, wherein a time interval in which the position of the semiconductor wafer is not changed is shorter than a time interval in which a characteristic parameter which relates to a contact between a test probe of the probe card and a contact point on the semiconductor wafer leaves a predetermined range as a result of the position change, caused by the temperature change, of the probe card.

18. The method according to claim 17, wherein a contact pressure between a test probe of the probe card and a contact point on the semiconductor wafer is used as the characteristic parameter.

19. The method according to claim 16, wherein test signals for functional testing are applied to the integrated circuit in a time interval in which the position of the semiconductor wafer is not changed.

20. The method according to claim 16, wherein the determination of the temperature of the probe card is carried out by at least one temperature sensor arranged on the probe card.
